(19) United States
(12) Patent Application Publication
(10) Pub. No.: US 2012/0099381 A1
(43) Pub. Date: Apr. 26, 2012

(54) EMBEDDED NON-VOLATILE MEMORY CELL, OPERATION METHOD AND MEMORY ARRAY THEREOF

(75) Inventors: Yimao Cai, Beijing (CN); Poren Tang, Beijing (CN); Ru Huang, Beijing (CN); Xiaoyan Xu, Beijing (CN)

(73) Assignee: PEKING UNIVERSITY, Beijing (CN)

(21) Appl. No.: 13/380,414

(22) PCT Filed: May 19, 2011
(86) PCT No.: PCT/CN2011/074296

§ 371 Date: Dec. 22, 2011

(30) Foreign Application Priority Data
Jun. 4, 2010 (CN) 201010199022.7

(51) Int. Cl. G11C 16/04; H01L 29/788

(52) U.S. Cl. 365/185.29; 257/315; 257/E29.3

(57) ABSTRACT

The present invention discloses an embedded non-volatile memory cell, an operation method and a memory array thereof. The method includes using a gate of a selection transistor as a floating gate of a memory, and using a source electrode and a drain electrode of the selection transistor as a source electrode and a drain electrode of the memory; and then changing a threshold of the device by varying the electrode voltages, thereby realizing a storage and change of information. The invention has advantages of a small area, a low operating voltage, high operating speed and high reliability.

### FIELD OF THE INVENTION

The present invention relates to a field of memory technology in ultra-large-scale integrated circuits, and in particular, to an embedded non-volatile memory cell, an operation method and a memory array thereof.

### BACKGROUND OF THE INVENTION

A non-volatile memory is a memory device in which information will not be lost after power-off. With a rapid development of portable and mobile apparatuses, such as a cell phone, a laptop, a palmtop and a USB flash disk, the non-volatile memory is widely used and has been one of the memories which occupy the largest market share. A standard non-volatile memory, for example, an EEPROM cell, has a double-layer polysilicon structure of a floating gate polysilicon and a control gate polysilicon. In order to realize a function of information storage, the floating gate polysilicon gate needs to be insulated from outside. The difference between a conventional CMOS logic process and an EEPROM cell process lies in that a double-layer polysilicon gate process, a tunneling oxide layer, a barrier oxide layer, a source/drain junction and a substrate doping concentration and so on, which makes the number of performing photolithography on a standard EEPROM cell is increased, and the difficulty and cost of the process is increased in embedded applications.

In order to lower a cost of the process and alleviate an influence of the process on other cells in the system, researches put more and more focus on a reduction of processes which are added when an embedded non-volatile memory is introduced, or on an implementation of an embedded non-volatile memory by employing a standard CMOS process. Using a single-layer gate process to form a non-volatile memory is a good selection. However, since a currently-proposed EEPROM memory cell with the single layer gate generally couples a voltage of a control gate to a floating gate transistor via a capacitor, an occupation area of the cell is large and an operating voltage is high, which is adverse to raise a storage density. Moreover, with a development of a technical node, a power voltage reduces continually and it is difficulty to obtain a high voltage in a chip, and a magnitude of the high voltage is also limited by a withstand voltage of a PN junction. Therefore, the current EEPROM memory cell with a single-layer gate still cannot effectively meet market requirements.

### SUMMARY OF THE INVENTION

In view of defects of the prior art, an object of the present invention is to provide an embedded non-volatile memory cell, an operation method and a memory array thereof. By using the array structure according to the present invention and corresponding programming, erasing and reading methods, the non-volatile memory cell according to the invention may attain an object of decreasing an area of the non-volatile memory cell, improving a read and write speed, decreasing a voltage during programming and erasing, and enhancing reliability of the memory cell.

A technical solution of the invention is as follows.

An operation method of an embedded non-volatile memory cell, characterized in that, a gate of a selection transistor is used as a floating gate of the memory cell, and a source electrode and a drain electrode of the selection transistor are used as a source electrode and a drain electrode of the memory cell, respectively, wherein;

a) an information erasing process includes applying a positive voltage pulse to a substrate electrode of the selection transistor, and floating the source electrode and the drain electrode of the selection transistor;

b) an information programming process includes connecting the substrate electrode and the source electrode of the selection transistor to a zero voltage, and connecting the drain electrode of the selection transistor to a positive voltage to generate hot electrons for programming;

c) an information reading process includes connecting the drain electrode of the selection transistor to a bias voltage, and connecting the source electrode and the substrate electrode to a zero potential.

Moreover, the selection transistor is an NMOS transistor.

Moreover, N-type impurities are implanted through an angled implantation into the drain of the NMOS transistor, and the NMOS transistor is a low-threshold or a negative-threshold NMOS transistor.

Moreover, in step a), information is erased via the positive voltage pulse to the substrate, and a pulse magnitude of the positive voltage pulse ranges from 4V to 8V; in step b), the programming process is a channel hot electron programming, and the positive voltage ranges from 4V to 7V; and in step c), the bias voltage is a positive voltage ranging from 0 to 2.5V.

An operation method of an embedded non-volatile memory cell, wherein, a gate of a selection transistor is used as a floating gate of the memory cell, a source electrode and a drain electrode of the selection transistor are used as a source electrode and a drain electrode of the memory cell, respectively, wherein:

a) an information erasing process includes: applying a positive voltage of nV to the substrate electrode and the source electrode of the selection transistor, and floating the drain electrode or applying a positive voltage of nV thereto;

b) an information programming process includes: connecting the substrate electrode and the source electrode of the selection transistor to a negative voltage, and connecting the drain electrode to a positive bias voltage, so as to generate hot electrons for programming;

c) an information reading process includes: connecting the drain electrode of the selection transistor to a bias voltage, and connecting the substrate electrode and the source electrode to a negative bias voltage.

Moreover, the selection transistor is a low-threshold or a negative-threshold NMOS transistor.

Moreover, N-type impurities are implanted through angled implantation into the drain of the NMOS transistor.

Moreover, in step a), information is erased by employing a Fowler-Nordheim tunneling method, and the positive voltage of nV ranges from 6V to 12V; in step b), the programming process is a channel hot electron programming, the negative voltage ranges from −2V to 0V, and the positive bias voltage ranges from 3V to 6V; in step c), the negative bias voltage ranges from −2V to 0V, and the bias voltage of the drain electrode ranges from 0V to 1V.

An embedded non-volatile memory cell includes a substrate layer (101), a deep N-well layer (102), an N-well layer (104) and a P-well layer (103); wherein a memory cell or array is manufactured on the P-well layer (103). The N-well layer (104) surrounds the P-well layer (103), and the deep N-well layer (102) is located under the N-well layer (104) and the P-well layer (103) and is connected with the N-well layer (104).

Moreover, a transistor of the memory cell is an NMOS transistor or a negative-threshold NMOS transistor; an n⁺ implantation layer (106) as a lead out of the deep N-well is disposed on a top of the N-well layer (104); a p⁺ implantation layer (107) as a lead out of the P-well is disposed between the N-well layer (104) and the source electrode or the drain electrode of the selection transistor; and a thick gate oxide layer (108) is disposed under the floating gate (109) of the selection transistor.

An embedded non-volatile memory array includes a plurality of memory cells, each of the memory cells including a selection transistor and a non-volatile memory cell; wherein in each of the memory cells, a gate of a selection transistor is connected with a word line of the memory array, one of a source/a drain of the selection transistor is connected with one of a source/a drain of the non-volatile memory cell, the other of the source/the drain of the selection transistor is connected with a common source terminal of the memory array, and the other of the source/the drain of the non-volatile memory cell is connected with a bit line of the memory array.

Moreover, the selection transistor is an NMOS transistor; each of the non-volatile memory cells is a low-threshold or a negative-threshold NMOS transistor; and N-type impurities are implanted through angled implantation into the drain of the non-volatile memory cell.

As compared with the prior art, the invention has following beneficial effects.

The non-volatile memory cell may employ a smaller area, the operating voltage may be low, the circuit complexity caused by designing a high voltage-generating circuit may be improved. Meanwhile, the programming and erasing speed of the device may be raised correspondingly, and the reliability may be enhanced.

### BRIEF DESCRIPTION OF THE DRAWINGS

FIG. 1 is a schematic diagram showing a sectional structure of a non-volatile memory cell according to the invention, wherein:
110—a bulk silicon substrate (p-doped)
111—an n⁻ source/drain
112—a thick gate oxide layer
113—a floating gate;

FIG. 2 is an electrode bias diagram during an erasing of a non-volatile memory cell of mode 1;

FIG. 3 is an electrode bias diagram during a programming of the non-volatile memory cell of mode 1;

FIG. 4 is an electrode bias diagram during a reading of the non-volatile memory cell of mode 1;

FIG. 5 is an electrode bias diagram during a programming of a non-volatile memory cell of mode 2;

FIG. 6 is an electrode bias diagram during a programming of the non-volatile memory cell of mode 2;

FIG. 7 is an electrode bias diagram during a reading of the non-volatile memory cell of mode 2;

FIG. 8 is a specific implementation method of a non-volatile memory cell, wherein:
101—a bulk silicon substrate
102—a deep N-well
103—a P-well
104—an N-well
105—an n⁺ source/drain
106—an n⁺ implantation as a lead out of a deep N-well
107—a p⁺ implantation as a lead out of a P-well
108—a thick gate oxide layer
109—a floating gate;

FIG. 9 is an array structure of non-volatile memory cells.

### DETAILED DESCRIPTION OF THE EMBODIMENTS

A structure of a non-volatile memory according to the invention is as shown in FIG. 1. The memory device includes an NMOS transistor with a thick gate oxide layer, wherein a gate of the NMOS transistor is isolated from outside and forms a floating gate of the non-volatile memory device, and a source/drain of the NMOS transistor forms a source/drain of the non-volatile memory device. The floating gate is surrounded by an oxide layer and isolated from outside, is floated during operating. A charge storage on the floating gate is changed with a change of a voltage of other electrodes, thus a threshold of the device is changed, so that a storage and a variation of information is realized. A programming, erasing and reading operation of the non-volatile memory cell are illustrated in detail below, which may be realized in following two modes.

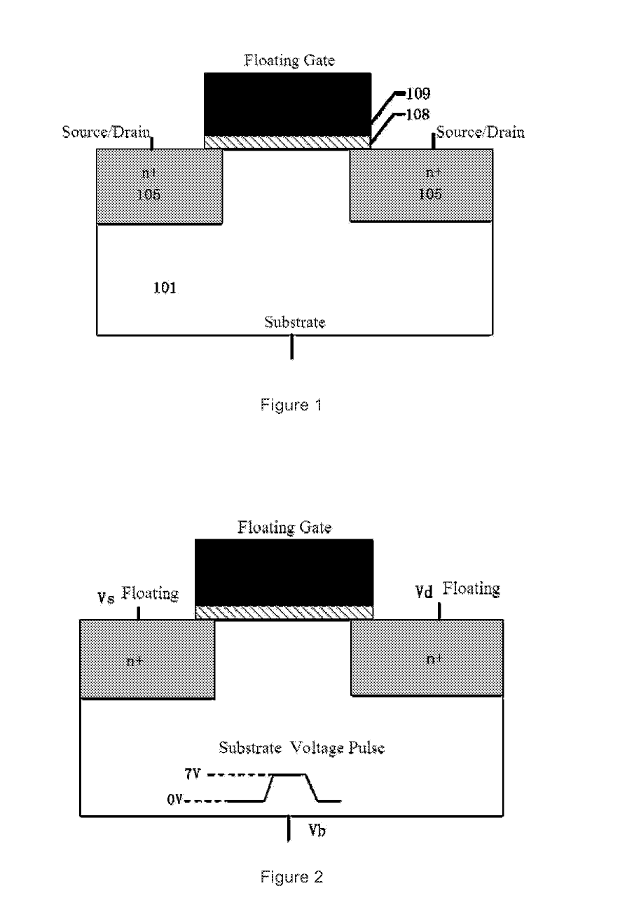

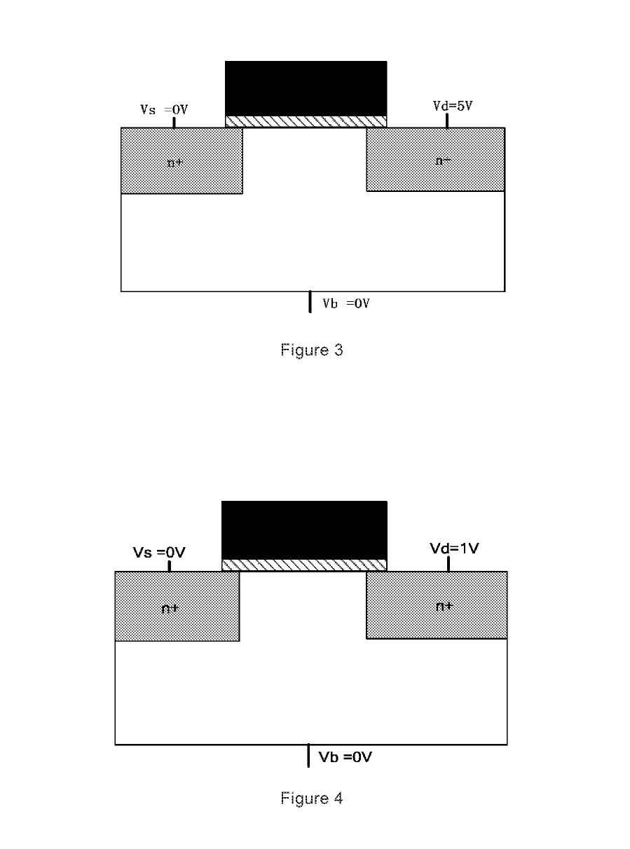

Mode 1: The memory cell employs a substrate hot hole erasing and a channel hot electron programming, a mechanism of which is as shown in FIGS. 2, 3 and 4. FIG. 2 shows a case of electrode biases during an erasing of the memory cell, in which a positive voltage pulse with Vb of 4V to 8V (6V, preferably) is applied to a substrate, and the other two electrodes Vs and Vd are floated. On a rising edge of the voltage pulse, holes are generated, and on a falling edge of the voltage pulse, the holes gain an energy under an action of a electric field to become hot holes. Part of the hot holes are implanted into the floating gate and the implanted holes make the charges stored on the floating gate change, so that the threshold voltage of the memory cell is changed, and an erasing is realized. A magnitude of the positive voltage pulse is selected in view of an erasing speed and a degree of difficulty to generate a high voltage. Additionally, it should be noted that because the source and drain are in a floating state, a breakdown of a PN junction between the source/drain and the substrate will not occur, and the magnitude of the erasing voltage is limited by a withstand voltage of the PN junction. FIG. 3 shows a case of the electrode biases during a programming of the memory cell, in which a channel hot electron programming is employed. Particularly, the substrate and the source terminal are grounded, and the drain is connected to a positive voltage ranging from 4V to 7V (5V, preferably). The holes stored on the floating gate may increase the voltage of the floating gate, and the voltage of the drain is coupled to the floating gate to further enhance a potential on the floating gate, so that the channel of the memory cell is turned on, and hot electrons are accelerated under an action of the electric field of the drain. P part of the hot electrons are implanted into the floating gate and are neutralized with the holes on the floating gate, thus the information in the memory cell is changed. FIG. 4 shows a case of the electrode biases of the memory cell when information is read, wherein the gate electrode is floated, and the drain electrode is applied a voltage bias ranging from 0V to 2.5V. When holes exist on the floating gate, the channel is turned on (after the memory cell is erased, holes exist on the floating gate), a signal current is read; otherwise, the channel is turned off (after the memory cell is programmed, no holes exists on the floating gate) and no signal current can be read.

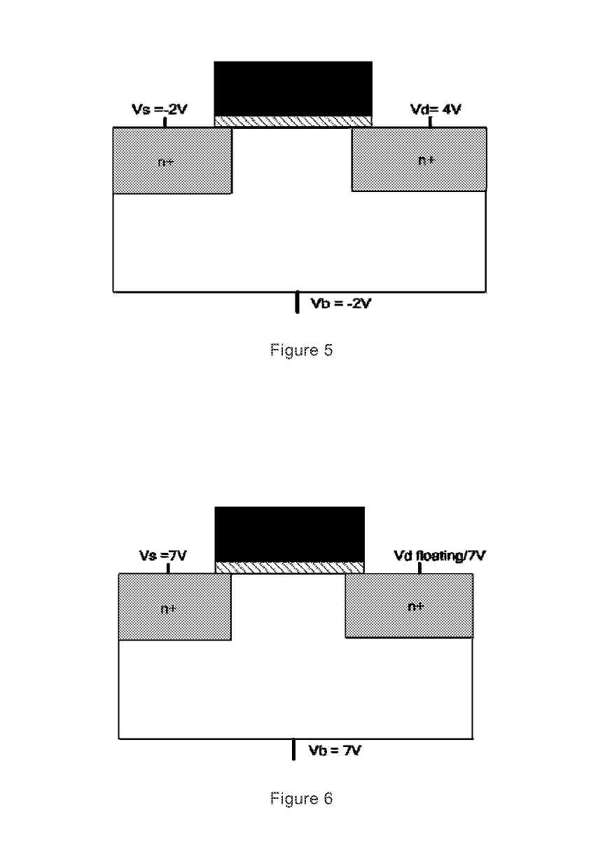

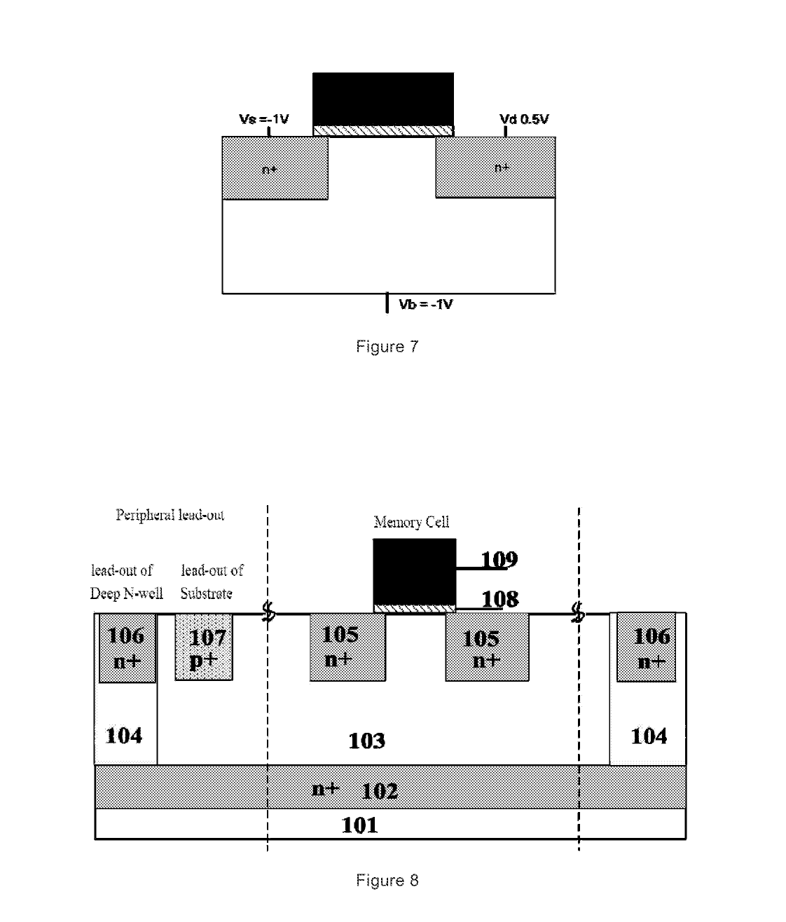

Mode 2; In order to increase the read signal current and a speed of write operation, as compared with the general solution, the non-volatile memory cell employ a negative source voltage to assist during operating, and the memory cell may employ a design of a low-threshold or a negative-threshold (a depletion type) NMOS transistor. In the view of process, only an N-type impurity (for example, phosphorus and arsenic) implantation needs to be added. The memory cell employs channel hot electrons for programming and a Fowler-Nordheim tunneling mechanism for erasing, and the specific operating mechanism is as shown in FIGS. 5, 6 and 7. FIG. 5 shows an electrode bias diagram during a programming, the source and the substrate are connected to a negative voltage of ranging from −2V to 0V, and the drain is connected to a positive bias ranging from 3V to 6V, so that the negative source voltage and substrate voltage make the NMOS transistor easier to be turned on, so that hot electrons are generated and implanted into the floating gate. The bias voltage during erasing is as shown in FIG. 6, the Fowler-Nordheim tunneling for erasing is employed, a positive voltage ranging from 6V to 12V is applied to the source and the substrate, the same voltage bias is applied to the drain, or the drain is floated. Because a current of Fowler-Nordheim tunneling is very small, a power consumption during operation may be lowered in such a mode, and at the same time, no high voltage exists on the PN junction between the substrate and the source/drain, thus a reliability of the device is not damaged. FIG. 7 shows the bias of the device during reading. Similarly, a negative source and substrate voltage bias is employed to increase the signal current during reading, that is, the source terminal and the substrate are connected to the same negative voltage ranging from −2V to 0V, and the drain is connected to a voltage ranging from 0V to 1V. In addition, during the programming (FIG. 3) and reading (FIG. 4) of mode 1, the method in FIG. 5 and FIG. 7 of mode 2 may also be employed, that is, the source and the substrate are connected to a negative voltage. By using a negative voltage bias to assist as well as a negative-threshold design, the programming speed and the signal current during reading may be increased. In order to raise a coupling coefficient of the drain to the floating gate, a process for angled implanting an N-type impurity (for example, phosphorus and arsenic) into the drain may be further added to the above two modes of memory cell, thereby increasing a overlapping between the drain and the floating gate.

As described above, voltage biases that are needed to be applied on the source, the drain and the substrate of the memory cell respectively is finally realized by the proposed non-volatile memory cell, wherein a implementation of voltage bias of the source and drain is the same as that of an general MOS transistor. In order to avoid that an application of substrate voltage interferes other memory cell in an embedded system, a deep N-well and an N-well are connected together during design and surround the memory cell or the memory array, so that the memory cell may be isolated from peripheral circuits on a wafer. As shown in FIG. 8, a deep N-well layer is disposed under the substrate layer of the memory cell (at this point, the P-well 103 in FIG. 8 is equivalent to the substrate in FIG. 1, and a p+ implantation lead out may be used), an N-well is disposed on the deep N-well layer and on two sides of the substrate, and a deep N-well lead out n+ implantation is disposed on the N-well. When the P-well voltage bias is 0 or a positive voltage, the voltage bias of the N-well is the same as that of the P-well. When the P-well voltage bias is a negative voltage, the voltage bias of the N-well is connected to zero potential. In addition, the cells in the memory array may share one lead out for substrate and one lead out for deep N-well, thus an area of the cell is not increased.

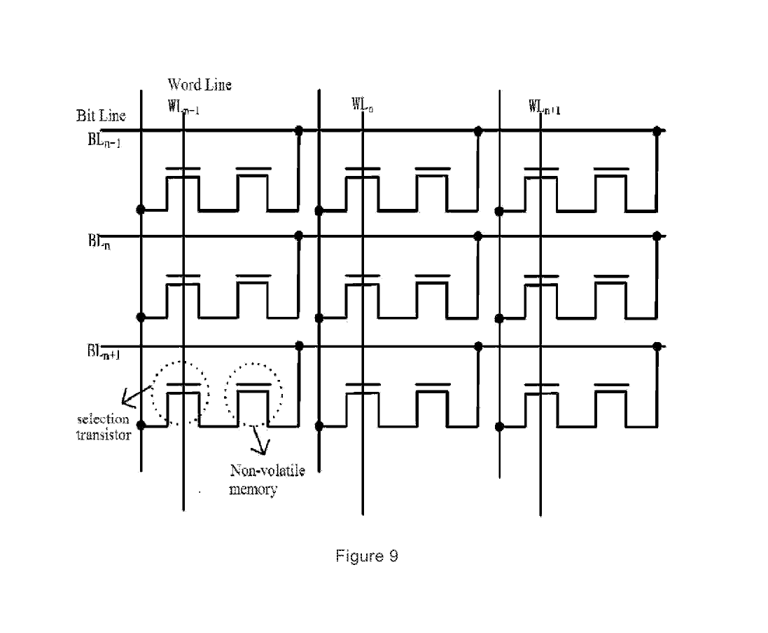

For the application of the non-volatile memory, an array structure of the non-volatile memory is formed. FIG. 9 shows a possible array structure of the above-proposed non-volatile memory cells. In consideration of selecting cells, a memory cell is formed by a selection transistor and a non-volatile memory together, wherein the selection transistor may be formed by employing a general MOS transistor, a gate of the selection transistor is used as a word line of the memory array, one terminal of a source/drain of the selection transistor is connected with one terminal of a source/drain of the non-volatile memory, and the other terminal of the source/drain of the selection transistor forms a common source structure of the array; one terminal of the source/drain of the non-volatile memory is connected with the selection transistor, and the other terminal is connected with a bit line of the array.

The invention puts forward a structure of a non-volatile memory cell, a corresponding programming, erasing and reading method, a implementation method and a possible array structure. The process of the proposed structure is compatible with an existing CMOS process, a cell area and an operating voltage of an embedded non-volatile device cell are effectively decreased, and a storage density and an operating speed are increased, thus indicating a wide perspective to be applied in a application of a storage with a high speed and a high storage density.

A structure of an embedded non-volatile memory cell according to the invention has been described in detail above. However, one skilled in the art should understand that, various modifications can be made without departing from the scope of the invention, and all these modifications will fall into the protection scope of the invention.

1. An operation method of an embedded non-volatile memory cell, characterized in that, a gate of a selection transistor is used as a floating gate of the memory cell, and a source electrode and a drain electrode of the selection transistor are used as a source electrode and a drain electrode of the memory cell, respectively, comprising:
a) an information erasing process comprising: applying a positive voltage pulse to a substrate electrode of the selection transistor, and floating the source electrode and the drain electrode of the selection transistor;
b) an information programming process comprising: connecting the substrate electrode and the source electrode of the selection transistor to a zero voltage, and connecting the drain electrode of the selection transistor to a positive voltage, so as to generate hot electrons for programming;
c) an information reading process comprising: connecting the drain electrode of the selection transistor to a bias voltage, and connecting the source electrode and the substrate electrode to a zero potential.

2. The method according to claim 1, characterized in that, the selection transistor is an NMOS transistor.

3. The method according to claim 2, characterized in that, N-type impurities are implanted through an angled implantation into the drain of the NMOS transistor, and the NMOS transistor is a low-threshold or a negative-threshold NMOS transistor.

4. The method according to claim 2, characterized in that, in step a), an information is erased via the positive voltage pulse to the substrate, and a pulse magnitude of the positive voltage pulse ranges from 4V to 8V; in step b), the programming method is a channel hot electron programming, and the positive voltage ranges from 4V to 7V; and in step c), the bias voltage is a positive voltage ranging from 0V to 2.5V.

5. An operation method of an embedded non-volatile memory cell, characterized in that, a gate of a selection transistor is used as a floating gate of the memory cell, and a source electrode and a drain electrode of the selection transistor are used as a source electrode and a drain electrode of the memory cell, respectively, comprising:
a) an information erasing process comprising: applying a positive voltage of nV to the substrate electrode and the source electrode of the selection transistor, and floating the drain electrode or applying a positive voltage of nV thereto;
b) an information programming process comprising: connecting the substrate electrode and the source electrode of the selection transistor to a negative voltage, and connecting the drain electrode to a positive bias voltage, so as to generate hot electrons for programming;
c) an information reading process comprising: connecting the drain electrode of the selection transistor to a bias voltage, and connecting the substrate electrode and the source electrode to a negative bias voltage.

6. The method according to claim 5, characterized in that, the selection transistor is a low-threshold or a negative-threshold NMOS transistor.

7. The method according to claim 6, characterized in that, N-type impurities are implanted through angled implantation into the drain of the NMOS transistor.

8. The method according to claim 6, characterized in that, in step a), an information is erased by employing a Fowler-Nordheim tunneling method, and the positive voltage of nV ranges from 6V to 12V; in step b), the programming method is a channel hot electron programming, the negative voltage ranges from −2V to 0V, and the positive bias voltage ranges from 3V to 6V; in step c), the negative bias voltage ranges from −2V to 0V, and the bias voltage of the drain electrode ranges from 0V to 1V.

9. An embedded non-volatile memory cell, characterized in that, comprising: a substrate layer (101), a deep N-well layer (102), an N-well layer (104) and a P-well layer (103); wherein a memory cell or array is manufactured on the P-well layer (103), the N-well layer (104) surrounds the P-well layer (103), and the deep N-well layer (102) is located under the N-well layer (104) and the P-well layer (103) and is connected with the N-well layer (104).

10. The memory cell according to claim 9, characterized in that, a transistor of the memory cell is an NMOS transistor or a negative-threshold NMOS transistor; an n⁺ implantation layer (106) as a lead out of the deep N-well is disposed on a top of the N-well layer (104); a p⁺ implantation layer (107) as a lead out of the P-well is disposed between the N-well layer (104) and the source electrode or the drain electrode of the selection transistor; and a thick gate oxide layer (108) is disposed under the floating gate (109) of the selection transistor.

11. An embedded non-volatile memory array, characterized in that, comprising a plurality of memory cells, each of the memory cells comprising a selection transistor and a non-volatile memory cell; wherein in each of the memory cells, a gate of the selection transistor is connected with a word line of the memory array, one of a source/a drain of the selection transistor is connected with one of a source/a drain of the non-volatile memory cell, the other of the source/the drain of the selection transistor is connected with a common source terminal of the memory array, and the other of the source/the drain of the non-volatile memory cell is connected with a bit line of the memory array.

12. The memory array according to claim 11, characterized in that, the selection transistor is an NMOS transistor; each of the non-volatile memory cells is a low-threshold or a negative-threshold NMOS transistor; and N-type impurities are implanted through angled implantation into the drain of each of the non-volatile memory cell.
